(19) United States
(12) Patent Application Publication
(10) Pub. No.: US 2021/0159253 A1
(43) Pub. Date: May 27, 2021

(54) DISPLAY PANEL AND DISPLAY DEVICE

(71) Applicants: Ordos Yuansheng Optoelectronics Co., Ltd., Inner Mongolia (CN); BOE Technology Group Co., Ltd., Beijing (CN)

(72) Inventors: Peirong HUO, Beijing (CN); Tianlei SHI, Beijing (CN); Wulijibaier TANG, Beijing (CN); Zhiqiang WANG, Beijing (CN); Peng LUO, Beijing (CN); Jianping ZHANG, Beijing (CN)

(73) Assignees: Ordos Yuansheng Optoelectronics Co., Ltd.; BOE Technology Group Co., Ltd.

(21) Appl. No.: 16/852,685

(22) Filed: Apr. 20, 2020

(30) Foreign Application Priority Data
Nov. 25, 2019 (CN) 201922070094.0

(51) Int. Cl. H01L 27/12; G02F 1/1339; G02F 1/1362

(52) U.S. Cl. CPC H01L 27/1237; G02F 2001/136295; G02F 1/136286; G02F 1/1339

(57) ABSTRACT

A display panel and a display device are provided. The display panel includes a base substrate and an encapsulation substrate which are oppositely arranged and are connected in cell alignment through sealant, a planarization layer on one side of the sealant facing the base substrate, a first metal layer on one side of the planarization layer facing the base substrate, wherein the first metal layer has a first area and a second area, an orthographic projection of the second area on the encapsulation substrate has a first overlapping area with an orthographic projection of the sealant on the encapsulation substrate, and a first isolation layer on one side of the second area away from the base substrate.

### CROSS-REFERENCES TO RELATED APPLICATION

This application claims priority to Chinese patent application No. 201922070094.0 filed on Nov. 25, 2019, which is incorporated herein by reference in its entirety.

### FIELD

The disclosure relates to the technical field of display, in particular to a display panel and a display device.

### BACKGROUND

The liquid crystal panel mechanical strength reliability test is usually used for evaluating an adhesive force, and through the experiment design, it is required that the failure of a liquid crystal panel in a certain environment is not allowed. Many methods such as four-axis bending, peeling and drop test can be used for evaluating product mechanical strength; and after common mechanical strength tests, the failures of a product include sheet cracking or peeling, wherein peeling is common, resulting in presence of liquid crystal leakage, color points or dirt, bubbles and the like during display of a liquid crystal panel.

The peeling of the liquid crystal panel refers to separation of an encapsulation substrate and a base substrate, and specific separation situations can include sealant separation, base substrate or encapsulation substrate peeling and the like. Peeling between a planarization layer and source-drain electrodes most commonly appears in the mechanical strength reliability test of the liquid crystal panel.

### SUMMARY

In one aspect, some embodiments of the disclosure provide a display panel. The display panel includes: a base substrate and an encapsulation substrate which are oppositely arranged and are connected in cell alignment through sealant; a planarization layer on one side of the sealant facing the base substrate; a first metal layer which is patterned and on one side of the planarization layer facing the base substrate, wherein the first metal layer has a first area and a second area, an orthographic projection of the second area on the encapsulation substrate has a first overlapping area with an orthographic projection of the sealant on the encapsulation substrate; and a first isolation layer on one side of the second area away from the base substrate.

In some embodiments, in an extension direction of the second area, the orthographic projection of the second area on the encapsulation substrate coincides with the orthographic projection of the sealant on the encapsulation substrate.

In some embodiments, the display panel further includes an interlayer insulating layer on one side of the first area facing the base substrate; and a first via hole penetrating through the interlayer insulating layer, wherein the first isolation layer is formed by the interlayer insulating layer, and the first area and the second area are connected through the first via hole.

In some embodiments, the display panel further includes a second metal layer which is patterned and on one side of the interlayer insulating layer facing the base substrate, wherein the second metal layer has a first part and a second part, the first part and the second area are arranged in a same layer, an orthographic projection of the second part on the encapsulation substrate has a second overlapping area with the orthographic projection of the sealant on the encapsulation substrate, the second overlapping area covers the first overlapping area, and a second isolation layer on one side of the second part away from the base substrate.

In some embodiments, the display panel further includes a gate insulating layer on one side of the first part facing the base substrate, a buffering layer on one side of the gate insulating layer facing the base substrate, and a second via hole penetrating through the gate insulating layer and the buffering layer, wherein the second isolation layer is formed by the gate insulating layer and the buffering layer, and the first part and the second part are connected through the second via hole.

In some embodiments, the display panel further includes a metal light shielding layer on one side of the buffering layer facing the base substrate, wherein the metal light shielding layer and the second part of the second metal layer are arranged in a same layer.

In some embodiments, a material of the interlayer insulating layer is silicon nitride or silicon oxide.

In some embodiments, a material of the planarization layer is a transparent acrylic material.

In some embodiments, the display panel further includes a passivation layer between the planarization layer and the sealant.

In another aspect, the disclosure further provides a display device including the display panel provided by the above any one of technical solutions.

### BRIEF DESCRIPTION OF THE DRAWINGS

FIG. 1 is a schematic structural diagram of a display panel according to an embodiment of the disclosure;

FIG. 2 is a section view of FIG. 1 along A-A′;

FIG. 3 is another schematic structural diagram of a display panel according to an embodiment of the disclosure; and

FIG. 4 is another schematic structural diagram of a display panel according to an embodiment of the disclosure.

### DETAILED DESCRIPTION

Technical solutions in embodiments of the disclosure are clearly and completely described in combination with accompanying drawings in the embodiments of the disclosure below, and obviously the described embodiments are only a part of embodiments of the disclosure but not all embodiments. On the basis of the embodiments in the disclosure, all other embodiments obtained by ordinary those skilled in the art without any creative fall into the scope of the disclosure.

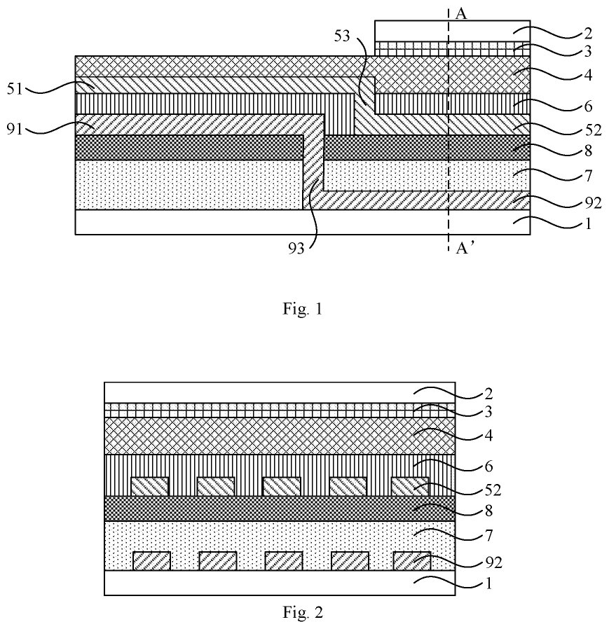

Referring to FIG. 1 and FIG. 2, the disclosure provides a display panel. The display panel includes: a base substrate 1 and an encapsulation substrate 2 which are oppositely arranged and are connected in cell alignment through sealant 3; a planarization layer 4 on one side of the sealant 3 facing the base substrate 1; and a first metal layer, which is patterned and formed on one side of the planarization layer 4 facing the base substrate 1, wherein the first metal layer has a first area 51 and a second area 52, a first overlapping area is formed between an orthographic projection of the second area 52 on the encapsulation substrate 2 and an orthographic projection of the sealant 3 on the encapsulation substrate 2, and a first isolation layer is formed on one side of the second area 52 away from the base substrate 1.

In the above display panel, the display panel includes the base substrate 1, the encapsulation substrate 2, the planarization layer 4 and the first metal layer, wherein the planarization layer 4 and the first metal layer are located between the base substrate 1 and the encapsulation substrate 2, and the first metal layer has the first area 51 and the second area 52. The first overlapping area is formed between the orthographic projection of the second area 52 of the first metal layer on the encapsulation substrate 2 and the orthographic projection of the sealant 3 on the encapsulation substrate 2, the first isolation layer is formed on one side of the second area 52 away from the base substrate 1, and the first isolation layer is in direct contact with the planarization layer 4, so that the contact area between the first metal layer and the planarization layer 4 in an area corresponding to the sealant 3 is reduced.

In the display panel provided by the disclosure, the first isolation layer isolates the second area 52 of the first metal layer from the planarization layer 4, and the first isolation layer is in direct contact with the planarization layer 4, so that the contact area between the first metal layer and the planarization layer 4 in the area corresponding to the sealant is reduced, the adhesive force of an inner film layer of the display panel can be improved, and the possibility of peeling failures between the planarization layer 4 and the first metal layer in the mechanical strength test is reduced.

Thus, according to the above display panel, the structure design in the display panel is changed, the peeling situation of the display panel is improved.

In some embodiments, referring to FIG. 1, in an extension direction of the second area 52, an orthographic projection of the sealant 3 on the encapsulation substrate 2 fully coincides with an orthographic projection of the second area 52 on the encapsulation. That is, as shown in FIG. 1, in an extension direction of the second area 52, the length of the sealant 3 is the same as the length of the second area 52.

On the basis of the above technical solution, in some embodiments, referring to FIG. 1 and FIG. 2, the display panel further includes an interlayer insulating layer 6 formed on one side of the first area 51 facing the base substrate 1, wherein the first isolation layer is formed by the interlayer insulating layer 6. The interlayer insulating layer is provided with a first via hole 53 penetrating therethrough, and the first area 51 and the second area 52 are connected through the first via hole 53.

It should be noted that the first area 51 and the second area 52 of the first metal layer are separated on the two sides through the interlayer insulating layer 6 in the display panel provided by the disclosure, the interlayer insulating layer 6 is provided with the first via hole, and accordingly the first area 51 and the second area 52 are electrically connected.

It should be noted that the first isolation layer is formed by the interlayer insulating layer 6, and with this structure, the display panel can be prepared without adding a procedure of preparing the first isolation layer.

On the basis of the above technical solution, referring to FIG. 1 and FIG. 2, the display panel further includes a patterned second metal layer formed on one side of the interlayer insulating layer 6 facing the base substrate 1. The second metal layer is provided with a first part 91 and a second part 92, the first part 91 and the second area 52 are arranged in the same layer, a second overlapping area is formed by an orthographic projection of the second part 92 on the encapsulation substrate 2 and the orthographic projection of the sealant 3 on the encapsulation substrate 2, the second overlapping area covers the first overlapping area, and a second isolation layer is formed on one side of the second part 92 away from the base substrate 1.

It should be noted that the first part 91 and the second area 52 are arranged in the same layer, that is, the first part 91 of the second metal layer and the second area 52 of the first metal layer can be prepared in the same layer, and with this structure, a preparation process of the display panel can be further simplified. In addition, a second isolation layer is formed between the second part 92 of the second metal layer and the second area 52, so that short circuit between the second metal layer and the first metal layer can be avoided.

It should be noted that the second overlapping area is formed between the orthographic projection of the second part 92 on the encapsulation substrate 2 and the orthographic projection of the sealant 3 on the encapsulation substrate 2, the second overlapping area covers the first overlapping area, and the area of the second part 92 of the second metal layer is larger than the area of the second area 52 of the first metal layer. With this structure, it can be further guaranteed that when the first part 91 and the second area 52 are arranged in the same layer, short circuit between the second metal layer and the first metal layer cannot occur.

On the basis of the above technical solution, in some embodiments, referring to FIG. 1 and FIG. 2, the display panel further includes a gate insulating layer 8 formed on one side of the first part 91 facing the base substrate 1, and a buffering layer 7 formed on one side of the gate insulating layer 8 facing the base substrate 1, wherein the second isolation layer is formed by the gate insulating layer 8 and the buffering layer 7, and the first part 91 and the second part 92 are connected through second via holes 93 penetrating through the gate insulating layer 8 and the buffering layer 7.

It should be noted that the first part 91 and the second part 92 of the second metal layer are separated on the two sides through the gate insulating layer 8 and the buffering layer 7 in the display panel provided by the disclosure, the gate insulating layer 8 and the buffering layer 7 are provided with second via holes 93, and accordingly the first part 91 and the second part 92 of the second metal layer can be electrically connected through the second via holes 93.

It should be noted that the second isolation layer is formed by the gate insulating layer 8 and the buffering layer 7, and with this structure, the display panel can be prepared without adding a procedure of preparing the second isolation layer.

On the basis of the above technical solution, in some embodiments, the display panel further includes a metal light shielding layer on one side of the buffering layer 7 facing the base substrate 1, wherein the metal light shielding layer and the second part 92 of the second metal layer are arranged in the same layer.

It should be noted that the second part 92 of the second metal layer and the metal light shielding layer are arranged in the same layer, and with this structure, the preparation process of the display panel can be further simplified.

In some embodiments, the material of the interlayer insulating layer 6 is silicon nitride or silicon oxide.

In some embodiments, the material of the planarization layer is a transparent acrylic material.

It should be noted that the acrylic material is an organic polymer material and has high viscidity, the adhesive force between the planarization layer 4 and the interlayer insulating layer 6 can be enhanced, accordingly the adhesive force of an inner film layer of the display panel according to the disclosure can be improved, and accordingly the possibility of peeling failures between the planarization layer 4 and the first metal layer in the mechanical strength test is reduced.

In some embodiments, the display panel further includes a passivation layer formed between the planarization layer 4 and the sealant 3.

It should be noted that three embodiments are provided for the position relation of the sealant 3, the second area 52 of the first metal layer and the second part 92 of the second metal layer.

### Embodiment I

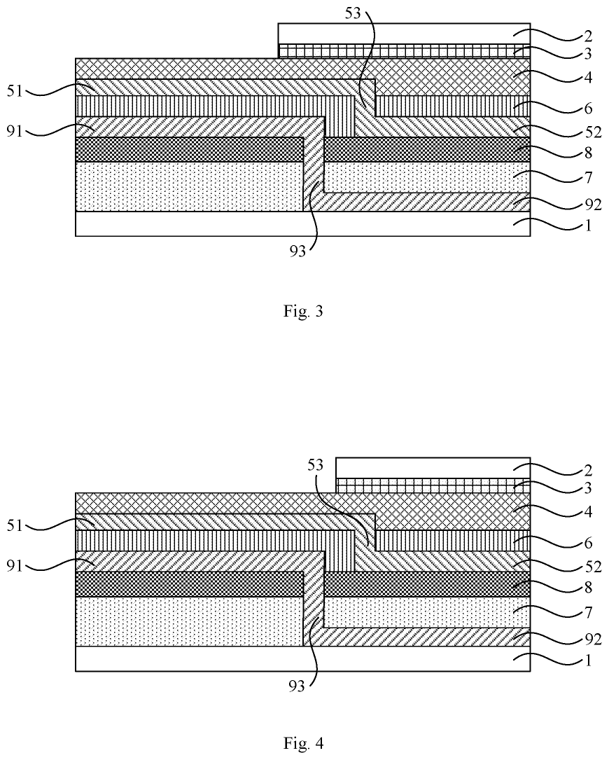

As shown in FIG. 3, in an extension direction of the second area 52, the length of the sealant 3 is larger than the length of the second area 52 of the first metal layer, and is larger than the length of the second part 92 of the second metal layer.

Specifically, in the display panel of the embodiment I, the second area 52 of the first metal layer and the planarization layer 4 are separated through the interlayer insulating layer 6, so that the contact area between the first metal layer and the planarization layer 4 in the area corresponding to the sealant 3 is reduced, the adhesive force between the planarization layer 4 and the interlayer insulating layer 6 can be enhanced, and accordingly, the possibility of peeling failures between the planarization layer 4 and the first metal layer in the mechanical strength test is reduced.

### Embodiment II

As shown in FIG. 4, in an extension direction of the second area 52, the length of the sealant 3 is larger than the length of the second area 52 of the first metal layer, and the length of the second part 92 of the second metal layer is larger than the length of the sealant 3.

Specifically, in the display panel in the embodiment II, the second area 52 of the first metal layer and the planarization layer 4 are separated through the interlayer insulating layer 6, the second area 52 of the first metal layer is larger, so that the contact area between the first metal layer and the planarization layer 4 in the area corresponding to the sealant 3 is greatly reduced, the adhesive force between the planarization layer 4 and the interlayer insulating layer 6 can be enhanced, and accordingly, the possibility of peeling failures between the planarization layer 4 and the first metal layer in the mechanical strength test is reduced.

### Embodiment III

As shown in FIG. 1, in an extension direction of the second are 52, the length of the second area 52 of the first metal layer is equal to the length of the sealant 3, the length of the second part 92 of the second metal layer is larger than the length of the sealant 3.

Specifically, in the display panel in the embodiment III, the second area 52 of the first metal layer and the planarization layer 4 are separated through the interlayer insulating layer 6, in the area corresponding to the sealant 3, the contact area between the first metal layer and the planarization layer 4 is zero, the adhesive force between the planarization layer 4 and the interlayer insulating layer 6 can be enhanced, and accordingly the possibility of peeling failures between the planarization layer 4 and the first metal layer in the mechanical strength test is reduced.

It should be noted that no procedures are added in the above embodiments, as shown in FIG. 2, fan-out wiring is designed in the metal light shielding layer, wiring signals of a gate layer are transmitted through the second via holes in the gate insulating layer 8 and the buffering layer 7, signal lines of source and drain electrodes descend to the gate layer on one side, facing the base substrate 1, of the interlayer insulating layer 6 through the first via hole, and the planarization layer 4 is in direct contact with the interlayer insulating layer 6 at the position corresponding to the sealant 3, and accordingly, the adhesive force of a film layer of a TFT panel is enhanced.

The disclosure further provides a display device including the display panel provided by any one of the above technical solutions.

Obviously, those skilled in the art can make various modifications and variations to the present disclosure without departing from the spirit and scope of the present disclosure. By doing this, if these modifications and variations to the present disclosure belong to the claims of the present disclosure and the scope of equivalent techniques thereof, the present disclosure also intends to include these modifications and variations inside.

1. A display panel, comprising:
a base substrate and an encapsulation substrate which are oppositely arranged and are connected in cell alignment through sealant;
a planarization layer on one side of the sealant facing the base substrate;
a first metal layer which is patterned and on one side of the planarization layer facing the base substrate, wherein the first metal layer has a first area and a second area, an orthographic projection of the second area on the encapsulation substrate has a first overlapping area with an orthographic projection of the sealant on the encapsulation substrate; and
a first isolation layer on one side of the second area away from the base substrate.

2. The display panel according to the claim 1, wherein in an extension direction of the second area, the orthographic projection of the second area on the encapsulation substrate coincides with the orthographic projection of the sealant on the encapsulation substrate.

3. The display panel according to the claim 2, further comprising:
an interlayer insulating layer on one side of the first area facing the base substrate; and
a first via hole penetrating through the interlayer insulating layer; wherein the first isolation layer is formed by the interlayer insulating layer, and the first area and the second area are connected through the first via hole.

4. The display panel according to the claim 3, further comprising:
a second metal layer which is patterned and on one side of the interlayer insulating layer facing the base substrate, wherein the second metal layer has a first part and a second part, the first part and the second area are in a same layer, an orthographic projection of the second part on the encapsulation substrate has a second overlapping area with the orthographic projection of the sealant on the encapsulation substrate, the second overlapping area covers the first overlapping area; and
a second isolation layer on one side of the second part away from the base substrate.

5. The display panel according to the claim 4, further comprising:
a gate insulating layer on one side of the first part facing the base substrate;
a buffering layer on one side of the gate insulating layer facing the base substrate; and
a second via hole penetrating through the gate insulating layer and the buffering layer, wherein the second isolation layer is formed by the gate insulating layer and the buffering layer, and the first part and the second part are connected through the second via hole.

6. The display panel according to the claim 5, further comprising a metal light shielding layer on one side of the buffering layer facing the base substrate, wherein the metal light shielding layer and the second part of the second metal layer are in a same layer.

7. The display panel according to the claim 3, wherein a material of the interlayer insulating layer is silicon nitride or silicon oxide.

8. The display panel according to the claim 1, wherein a material of the planarization layer is a transparent acrylic material.

9. The display panel according to claim 1, further comprising a passivation layer between the planarization layer and the sealant.

10. A display device, comprising the display panel according to claim 1.
